(19) United States
(12) Patent Application Publication
(10) Pub. No.: US 2024/0186360 A1
(43) Pub. Date: Jun. 6, 2024

(54) PIXEL UNIT, OPTICAL DETECTOR, FORMATION METHOD, THE READOUT METHOD

(71) Applicants: Semiconductor Manufacturing International (Beijing) Corporation, Beijing (CN); Semiconductor Manufacturing International (Shanghai) Corporation, Shanghai (CN)

(72) Inventors: Qiongtao WU, Beijing (CN); Dayong YAN, Beijing (CN); Xinxiao ZHANG, Beijing (CN)

(21) Appl. No.: 18/510,325

(22) Filed: Nov. 15, 2023

(30) Foreign Application Priority Data
Dec. 5, 2022 (CN) 202211548202.0

(51) Int. Cl. H01L 27/146; G01S 7/481; G01S 17/894

(52) U.S. Cl. CPC H01L 27/14656; G01S 7/4816; G01S 17/894; H01L 27/1463; H01L 27/14636; H01L 27/14689

(57) ABSTRACT

A pixel unit includes: a base, the base including a substrate, a photosensitive element, and memory nodes; overflow doping regions in the second surface of the substrate; and overflow interconnection structures electrically connected to the overflow doping regions. Vertical-overflow-drain structures are formed between the overflow doping regions and the memory nodes, allowing the charge stored in the memory nodes to be discharged at a certain rate through the overflow interconnection structures. This configuration reduces the oversaturation of memory nodes effectively without altering the exposure time or affecting circuit power consumption, thereby addressing background noise issue. Furthermore, the memory nodes and the overflow doping regions are in the first and second surfaces of the substrate, respectively. Therefore, the placement of the overflow doping regions does not affect the area of the pixel unit, and the resolution of the photosensor is preserved.

### CROSS-REFERENCES TO RELATED APPLICATION

This application claims the priority of Chinese Patent Application No. 202211548202.0, filed on Dec. 5, 2022, the content of which is incorporated herein by reference in its entirety.

### TECHNICAL FIELD

The present disclosure generally relates to the field of semiconductor manufacturing and, more particularly, relates to a pixel unit, an optical detector, the formation method and the readout method.

### BACKGROUND

As human-machine interaction methods such as gesture recognition and motion tracking continue to evolve, there is a growing demand for low-cost, and real-time three-dimensional cameras. Among these, Indirect Time-of-Flight (iTOF) three-dimensional cameras, owing to their lower computational power requirements, higher spatial resolution, and relatively mature technological foundation, represent a promising direction in short-range (ranging from 1 meter to 10 μmeters) three-dimensional distance measurement technology.

Both indirect Time-of-Flight (iTOF) and Direct Time-of-Flight (dTOF) distance measurement methods rely on Time-of-Flight (TOF) to measure distances. This involves calculating the transmission time of optical signals from transmission to reception to determine the distance of the target object. For direct Time-of-Flight distance measurement, distances are calculated by directly computing the transmit-receive time of pulse light source. In contrast, indirect Time of Flight distance measurement calculates distances by computing the phase difference between transmitted and received signals of continuous wave light source.

Various types of optical detectors, such as Pinned Photodiodes (P(pd)), Gate Assisted Photodiodes (GA(pd)), and Current Assisted Photodiodes (CA(pd)), can be used in iTOF distance measurements.

To calculate the phase difference between the transmitted and received optical signals, the readout method employed by optical detectors in indirect Time-of-Flight distance measurements shares common characteristics. One such characteristic is memory. Within a single pixel unit of an optical detector, there are two or more memory nodes to hold photogenerated carriers produced during one exposure cycle temporarily, and the phase is calculated by computing their difference after one exposure cycle. Another characteristic is synchronization. The opening frequency of memory nodes and the phases within a single pixel unit are synchronized with the frequency and phase height of the optical signals emitted.

However, existing optical detectors suffer from significant background noise issue and face challenges in balancing such as area, exposure time and other aspects.

The disclosed devices and methods are directed to at least partially alleviate one or more problems set forth above and to solve other problems in the art.

### SUMMARY

One aspect of the present disclosure provides a pixel unit for an optical detector. The pixel unit includes a base, including a substrate having a first surface and a second surface opposite to the first surface. A photosensitive element is in the first surface of the substrate. A plurality of memory nodes are in the first surface of the substrate and are spaced apart from the photosensitive element. A plurality of overflow doping regions are in the second surface of the substrate. The locations of the plurality of overflow doping regions correspond to locations of the plurality of memory nodes, and a doping type of the plurality of overflow doping regions is same as a doping type of the plurality of doping regions of the plurality of memory nodes. A plurality of overflow interconnection structures are over the plurality of overflow doping regions. The plurality of overflow interconnection structures are electrically connected to the plurality of overflow doping regions.

Another aspect of the present disclosure provides an optical detector. The optical detector includes a pixel unit. The pixel unit includes the pixel unit disclosed in the present disclosure.

Another aspect of the present disclosure provides a method for forming an optical detector. In the method, a base is provided. The base includes a substrate having a first surface and a second surface opposite to the first surface. A photosensitive element is provided in the first surface of the substrate. A plurality of memory nodes are provided in the first surface of the substrate and are spaced apart from the photosensitive element. A plurality of overflow doping regions are formed in the second surface of the substrate. The second surface is opposite to the first surface. Locations of the plurality of overflow doping regions correspond to locations of the plurality of memory nodes, and a doping type of the plurality of overflow doping regions is same as a doping type of the plurality of doping regions of the memory nodes. A plurality of overflow interconnection structures are over the plurality of overflow doping regions. The plurality of overflow interconnection structures are electrically connected to the plurality of overflow doping regions.

Another aspect of the present disclosure provides a readout method for an optical detector. The optical detector includes the optical detector disclosed in the present disclosure. The readout method includes activating and deactivating a plurality of switch devices alternately at a predetermined frequency during one exposure cycle, and connecting the plurality of overflow interconnection structures to external circuits simultaneously at predetermined time points to discharge charge at the same rate. Each of the plurality of memory nodes connects to the photosensitive element via one of the plurality of switch devices.

### BRIEF DESCRIPTION OF THE DRAWINGS

The following drawings are merely examples for illustrative purposes according to various disclosed embodiments and are not intended to limit the scope of the present disclosure.

FIG. 1 illustrates a schematic cross-sectional structure of a single pixel unit in an optical detector using an indirect time-of-flight distance measurement method.

FIG. 2 illustrates a signal processing schematic for distance computation by the optical detector shown in FIG. 1.

FIGS. 3 to 5 illustrate schematic cross-sectional views of an exemplary optical detector at various stages during formation according to some embodiments of the present disclosure.

FIG. 6 illustrates a schematic of timing diagram of signal in an exposure process of an exemplary pixel unit in an exemplary readout method of an optical detector according to some embodiments of the present disclosure.

### DETAILED DESCRIPTION

Various embodiments provide a pixel unit, an optical detector, and their formation and readout methods. In one embodiment, the background noise issue discussed herein may then be solved with no increase in the area, exposure time, and/or power consumption.

It is evident that the background noise issue exists in optical detectors using in indirect time-of-flight distance measurement methods. During the collection of optical signals, ambient light is concurrently gathered as background signals in pixel units.

FIG. 1 illustrates a schematic cross-sectional structure of a pixel unit in an optical detector using indirect time-of-flight distance measurement method.

The pixel unit of the optical detector may include: a photosensitive element (pd), the photosensitive element including photodiode which includes a PN junction; two memory nodes (mn), including the memory node mn1 and the memory node mn2, on either side of the photosensitive element (pd). For example, the memory node mn1 is connected to the photosensitive element (pd) via a transmission tube tx1, and the memory node mn2 is connected to the photosensitive element (pd) via a transmission tube tx2.

The main photosensitive process of the pixel unit may include: generating photoelectrons by the photodiode of the photosensitive element, storing the photoelectrons in the memory nodes during one exposure cycle, activating transmission tube tx1 and tx2 alternately at a predetermined frequency to enable electrons to be stored in different memory nodes according to the frequency and the phase of the emission signal; and after one exposure cycle, calculating the phase difference based on the difference in stored electrons between the memory node mn1 and the memory node mn2, and thus obtaining distance measurement.

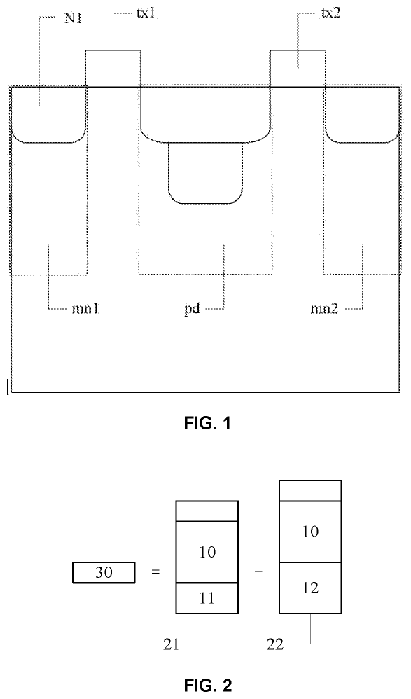

As shown in FIG. 2, a signal 21 stored in the memory node mn1 includes: a background signal 10 and a signal 11 collected at the memory node mn1. A signal 22 stored in the memory node mn2 includes: a background signal 10 and a signal 12 collected at the memory node mn2.

An effective signal 30 is the difference between the signals 21 stored in the memory node mn1 and the signal 22 stored in the memory node mn2, specifically the difference between the signal 11 collected at the memory node mn1 and the signal 12 collected at the memory node mn2.

It is evident that under strong outdoor ambient light conditions, the intensity of the ambient light can be excessively high, causing rapid oversaturation in the memory nodes in individual pixel unit of an optical detector. Oversaturation refers to the phenomenon where the signals received by the memory node exceed its maximum storage capacity. When oversaturation occurs in memory node, it not only renders the signal collected by the pixel unit ineffective but may also affect the detection results of adjacent pixels.

The use of a filter is a mature and widely adopted method to address the background noise issue. However, the installation of optical filters alone may not reduce the background noise to a sufficiently low level. For example, in distance measurements conducted under sunlight, a signal light with a wavelength of 940 nm is typically used. To address the background noise issue, optical filters are often installed to filter out ambient light outside the range of 940±50 nm. The installation of these filters can reduce the intensity ratio of background noise to signal from 20000:1 to 2000:1.

Multi-frame fusion is another method to improve the background noise issue. It involves reducing the exposure time in each exposure cycle to prevent memory nodes from becoming oversaturated, while merging the signals simultaneously from a plurality of exposure cycles into a single frame, thereby maintaining a constant total exposure time.

While the method of multi-frame fusion may improve the background noise issue, it may also introduce additional noises. Moreover, acquiring a single-frame image requires more time and is accompanied by more intricate computational operations and higher circuit power consumption.

Another method to address the background noise issue is the incorporation of a background suppression circuit. Background suppression circuits are categorized into various types based on their principles, including voltage domain, charge domain and others. Regardless of the type, background suppression circuits tend to be rather complex. The incorporation of background suppression circuits may require the inclusion of capacitors in each pixel circuit. However, the capacitor fabrication process is not entirely compatible with existing sensor chip processes. The addition of certain capacitor structures may require the introduction of non-conventional N-well processes, inevitably increasing the area of the pixel unit and reducing the spatial resolution of the optical detector. Furthermore, it may increase the power consumption of the optical detector. These factors are unfavorable for the application of optical detectors in mobile devices such as smartphones.

To address these technical issues, the present disclosure provides a pixel unit, an optical detector, a formation method and a readout method. A plurality of overflow doping regions may be in a second surface of a substrate, where the second surface is opposite to a first surface of the substrate. For example, locations of the overflow doping regions correspond to locations of the memory nodes, and a doping type of the overflow doping regions is same as a doping type of the doping regions of the memory nodes. A plurality of vertical-overflow-drain structures may be formed between the overflow doping regions and the memory nodes, enabling charges stored at the memory nodes to be discharged at a certain rate through overflow interconnection structures. This structure may effectively reduce the oversaturation at the memory nodes and thus solve the background noise issue without altering the exposure time or affecting circuit power consumption. Furthermore, the memory nodes and the overflow doping regions may be in the first surface and the second surface of the substrate, respectively. Hence, the placement of the overflow doping regions may not affect the area of pixel unit, and the resolution of optical detector may be preserved.

To make the objectives, features, and advantages of the present disclosure more readily understandable, specific embodiments of the disclosure are described in detail below, in conjunction with the accompanying drawings.

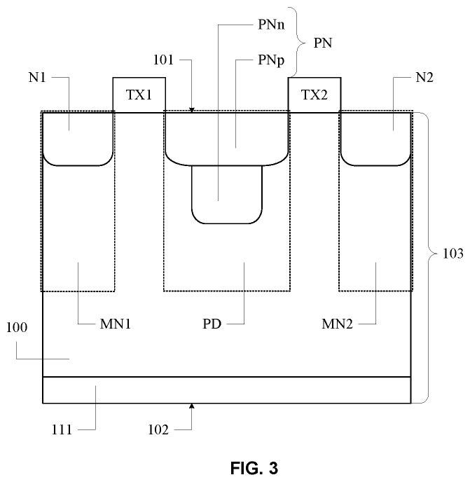

FIGS. 3 to 5 illustrate schematic cross-sectional views of an exemplary optical detector at various stages during formation according to some embodiments of the present disclosure.

The optical detector may include at least one pixel unit, and the at least one pixel unit is formed through the same process. FIGS. 3 to 5 illustrate the formation process of the pixel unit.

As shown in FIG. 3, a base 103 is formed. The base 103 includes a substrate 100, the substrate 100 having a first surface 101 and a second surface 102 opposite to the first surface 101; a photosensitive element (pd) in the first surface 101 of the substrate 100; a plurality of memory nodes in the first surface 101 of the substrate 100, with spacings between the memory nodes and the photosensitive element (pd).

The base 103 may be used to provide a foundation of processes for subsequent steps.

The substrate 100 may be used to provide a working platform for subsequent processes. The material of the substrate 100 may include single-crystal silicon, polycrystalline silicon, and/or amorphous silicon. The material of the substrate 100 may include silicon, germanium, gallium arsenide, and/or silicon-germanium compounds. The substrate 100 may also include those with epitaxial layers or silicon structures on epitaxial layers. The material of the substrate 100 may include other semiconductor materials, and the present disclosure is not limited thereto. As shown in FIG. 3, the material of the substrate 100 is silicon.

The photosensitive element (pd) in the first surface 101 is used to absorb photons and perform photoelectric conversion to generate photogenerated carriers.

In some embodiments of the present disclosure, the photosensitive element (pd) may include an PN junction PN in the first surface 101. As shown in FIG. 3, the photosensitive element (pd) includes a P-type photosensitive doping region PNp and a N-type photosensitive doping region PNn. For example, the P-type photosensitive doping region PNp and the N-type photosensitive doping region PNn are arranged sequentially along a direction from the first surface 101 to the second surface 102, and P-type photosensitive doping region PNp and N-type photosensitive doping region PNn are in contact with each other to form the PN junction PN.

The memory nodes are used for storing the photogenerated carriers.

In some embodiments of the present disclosure, a method is provided for forming an indirect time-of-flight three-dimensional optical detector. Specifically, the optical detector formed by the method is an indirect time-of-flight three-dimensional optical detector. The photogenerated carriers stored in the memory nodes are used to calculate the phase difference. Therefore, the base 103 may include a plurality of memory nodes. In other words, a plurality of memory nodes may be formed in the substrate 100 during the formation of the base 103.

Specifically, as shown in FIG. 3, the pixel unit includes the memory node mn1 and the memory node mn2. For example, in the plane parallel to the first surface 101, the memory node mn1 and the memory node mn2 are on either side of the photosensitive element (pd) in the substrate 100.

Furthermore, as shown in FIG. 3, the memory nodes include: a plurality of storage doping regions. Therefore, the pixel unit includes: a storage doping region N1 and a storage doping region N2. For example, in the plane parallel to the first surface 101, the storage doping region N1 and the storage doping region N2 are on either side of the PN junction PN in the first surface 101.

In some embodiments of the present disclosure, the substrate 100 may be a P-doped substrate, and therefore the storage doping regions may be N-doped regions, i.e., both the storage doping regions N1 and N2 are N-doped regions.

Specifically, in some embodiments illustrated in FIG. 3, the doping concentration of the substrate 100 may be less than 10¹³/cm³; the doping concentration of the storage doping regions in the memory nodes may be greater than 10¹⁷/cm³; the doping concentrations of the P-type photosensitive doping region PNp and the N-type photosensitive doping region PNn may be greater than 10¹⁵/cm³.

In addition, the steps for forming the base 103 may include: forming switch devices to control the conduction and cutoff between the photosensitive element (pd) and the memory nodes.

For example, the base 103 includes: the PN junction PN in the first surface 101 of the substrate 100, and the storage doping regions N1 and N2 on either side of the PN junction PN. The steps for forming the substrate 103 includes: forming a switch device tx1 in the first surface 101 between the storage doping region N1 and the PN junction PN, and forming a switch device tx2 in the first surface 101 between the storage doping region N2 and the PN junction PN.

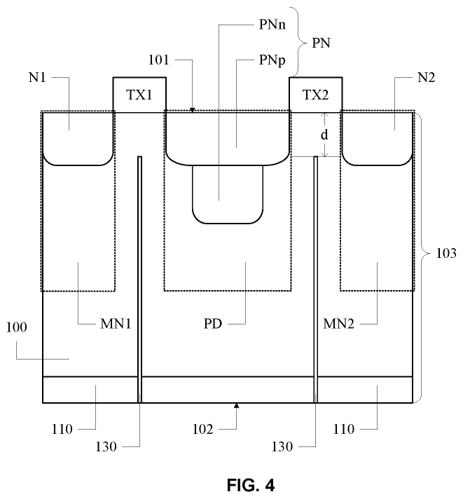

As shown in FIG. 3 and FIG. 4, a plurality of overflow doping regions 110 are formed in the second surface 102 of the substrate 100. For example, the locations of the overflow doping regions 110 correspond to the locations of the memory nodes, and the doping type of the overflow doping regions 110 are the same as the doping type of the doping regions of the memory nodes.

A plurality of vertical-overflow-drain structures may be formed between the overflow doping regions 110 and the memory nodes, allowing the charges stored in the memory nodes to be discharged at a certain rate. It may reduce the oversaturation of the memory nodes and solve background noise issue effectively.

Furthermore, the overflow doping regions 110 may be formed in the second surface 102 of the substrate 100, and the second face 102 is opposite to the first surface 101 of the substrate 100. Therefore, the formation of the overflow doping regions 110 may not affect the area of the pixel unit, and the resolution of optical detector may be preserved.

In some embodiments of the present disclosure, the substrate 100 may be P-doped, and the storage doping regions of the memory nodes may be N-doped; therefore, the overflow doping regions 110 may be N-doped. Thus, the plurality of vertical-overflow-drain structures of NPN may be formed between the memory nodes, the substrate 100, and the overflow doping regions 110.

In some embodiments of the present disclosure, the doping peak depth of the overflow doping regions 110 may be less than 0.1 μm. By controlling the doping peak depth of the overflow doping regions 110 to form shallow lightly doped regions, it may minimize the adverse effects on the performance of the photosensitive element (pd) and the memory nodes and also aid in controlling the thickness of the substrate 110 while facilitating the formation of the vertical-overflow-drain structures, even when the overflow doping regions 110 are formed closely to the surface of the second surface 102. For example, the doping concentration of the overflow doping regions 110 are greater than 10¹⁷/cm³.

In some embodiments of the present disclosure, as shown in FIG. 3 and FIG. 4, the plurality of memory nodes are in the base 103. Therefore, the plurality of overflow doping regions 110 are in the second surface 102 of the substrate 100, and one of the plurality of overflow doping regions corresponds to one of the plurality of memory nodes.

One of the plurality of overflow doping regions may correspond to one of the plurality of memory nodes. In other words, a vertical-overflow-drain structure may be formed between one of the plurality of overflow doping regions 110, its corresponding memory node, and the substrate therebetween, thereby forming an electron outflow channel to reduce the oversaturation of the corresponding memory node.

Specifically, one of the plurality of overflow doping regions may correspond to one of the plurality of memory nodes. Therefore, on the second surface 102, the projections of the storage doping regions of the memory nodes may be within the range of the overflow doping regions 110. For example, on the second surface 102, the projection of the storage doping region N1 is in the range of the corresponding overflow doping regions 110, and the projection of the storage doping region N2 is in the range of the corresponding overflow doping regions 110, as shown in FIG. 4.

It should be noted that the method of formation may be suitable for the formation of back-illuminated optical detectors. In other words, in the optical detectors formed herein, light enters from the second surface 102 and travels toward the base 103 along the direction from the second surface 102 towards the first surface 101. Therefore, after forming the base 103 and before forming the overflow doping regions 110 in the second surface 102 of substrate 100, the method of formation may further include: thinning the substrate 100 from the second surface 102.

In some embodiments of the present disclosure, the steps of forming the overflow doping regions 110 in the second surface 102 of the substrate 100 may include: forming a pre-doping region 111 in the second surface 102, at a location at least corresponding to a location of the memory nodes, as shown in FIG. 3; forming deep trench isolation structures 130 in the base 103 between the photosensitive element (pd) and the memory nodes, with the deep trench isolation structures 130 extending from the second surface 102 towards the first surface 101 and at least passing through the pre-doping region 111, as shown in FIG. 4.

The pre-doping region 111 may be used to form the overflow doping regions 110.

In some embodiments of the present disclosure, the steps of forming the pre-doping region 111 in the second surface 102 may be carried out using maskless ion implantation. The maskless ion implantation process for forming the pre-doping region 111 may be advantageous as it avoids the use of a mask, reduces process costs effectively, eliminates the need for mask alignment, and ensures high yield.

In some embodiments of the present disclosure, the overflow doping regions 110 may be N-doped regions, the doping concentration of the overflow doping regions 110 may be greater than 10¹⁷/cm³, and the doping peak depth of the overflow doping regions 110 may be less than 0.1 μm. Therefore, the pre-doping region 111 may be an N-doped region with a doping concentration greater than 10¹⁷/cm³, and the maskless ion implantation process may ensure that the doping peak depth of the pre-doping region 111 is less than 0.1 μm.

Therefore, as shown in FIG. 3, in the direction parallel to the second surface 102, the pre-doping region 111 covers the entire pixel unit. For example, the pre-doping region 111 extends not only in the region corresponding to the memory nodes but also into the region corresponding to the photosensitive element (pd).

In some embodiments illustrated in FIG. 3 and FIG. 4, in the second surface 102, the pre-doping region 111 extends from the region corresponding to the memory node mn1, through the region corresponding to photosensitive element (pd), and further into the region corresponding to the memory node mn2.

A plurality of deep trench isolation (DTI) structures 130 may be employed to isolate the pre-doping region 111 to form the plurality of overflow doping regions 110 corresponding to the plurality of memory nodes.

In some embodiments illustrated in FIG. 4, the deep trench isolation structures 130 extend to the depth of the PN junction PN, and the distance d between the end of the deep trench isolation structure 130 and the first surface 101 is greater than 0.3 μm. For example, the deep trench isolation structures 130 are between the photosensitive element (pd) and the memory nodes, and extend deep into the substrate 100, reaching the depth of the PN junction PN. This configuration may ensure both electrical isolation and optical isolation between the photosensitive element (pd) and the memory nodes. It may also limit the distance d between the end of the deep trench isolation structure 130 and the first surface 101 to ensure normal electron flow between the photosensitive element (pd) and the memory nodes when a switch device is activated.

In some embodiments of the present disclosure, the steps of forming the deep trench isolation structures 130 may include: exposing, developing, and etching the second surface between the photosensitive element (pd) and the memory nodes in the substrate 100 to form deep trenches; filling the deep trenches to form the deep trench isolation structures 130.

Specifically, the step of filling the deep trenches may include: forming a first material layer and a second material layer sequentially on the sidewalls and the bottom of the deep trenches. For example, when both the first material layer and the second material layer are dielectric layers, the refractive index of the material in the second material layer is greater than the refractive index of the material in the first material layer; Or the first material layer is a dielectric layer, and the second material layer is a metal layer.

In some embodiments illustrated in FIG. 4, the material of the first material layer is silicon dioxide, and the material of the second material layer is silicon nitride. In some other embodiments, the material of the second material layer may be copper, tungsten, aluminum, or a combination thereof. Specifically, the thickness of the first material layer may be in the range of 50 nm to 200 nm, and the thickness of the second material layer may be in the range of 100 nm to 400 nm.

The overflow doping regions 110 may be formed by isolating the pre-doping region 111 through deep trench isolation structures. Therefore, as shown in FIG. 4, the portions of the pre-doping region 111 corresponding to the memory nodes are suitable for forming the overflow doping regions 110. The pre-doping region 111 furthers extends between adjacent deep trench isolation structures 130, distributed in the portion of the second surface 102 corresponding to the photosensitive element (pd).

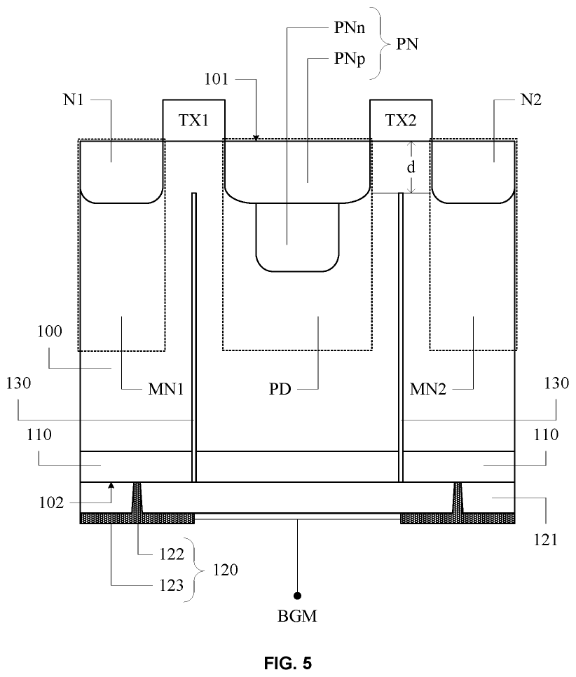

As shown in FIG. 5, overflow interconnection structures 120 are formed over the overflow doping regions 110, electrically connecting to the overflow doping regions 110.

The overflow interconnection structures 120 may be suitable for facilitating the connection between the overflow doping regions 110 and external circuits. Thus, the vertical-overflow-drain structures may be connected into external circuits and the flow of charge may be formed.

In some embodiments of the present disclosure, the plurality of memory nodes are formed in the base 103, and the plurality of overflow doping regions 110 corresponding to the memory nodes are formed in the second surface 102 of the substrate 100. Therefore, in the steps of forming the overflow interconnection structures 120 over the overflow doping regions 110, the plurality of overflow interconnect structures 120 are formed over the overflow doping regions 110, with one of the plurality of overflow interconnect structures 120 corresponding to one of the plurality of overflow doping regions 110.

In some embodiments of the present disclosure, on the second surface 102, the projections of the memory nodes may be within the projection range of the overflow interconnection structures 120. The formation method is applicable for back-illuminated optical detectors, where light enters from the second surface 102 to the substrate 100. By ensuring that the projections of the memory nodes fall within the projections of the overflow interconnection structures 120, even if the overflow interconnection structures 120 cover the memory nodes, optical isolation of the memory nodes may be achieved. It may also prevent incident light from reaching the memory nodes and the formation of parasitic photoelectrons effectively.

In some embodiments of the present disclosure, the steps of forming the overflow interconnection structures 120 over the overflow doping regions 110 may include: forming a protective layer 121 over the second surface 102, where the protective layer 121 is at least over the overflow doping regions 110; forming through-holes through the protective layer 121, with the through-holes over the overflow doping regions 110 and exposing the bottom of the overflow doping regions 110; forming overflow interconnection structures 120 within the through-holes, where the overflow interconnection structures 120 extend onto the protective layer 121 over the overflow doping regions 110.

The protective layer 121 may be used to achieve electrical insulation between the overflow doping regions 110 and the overflow interconnection structures 120.

Specifically, the material of the protective layer 121 may be silicon dioxide. In some embodiments of the present disclosure, the material of the protective layer 121 may be other dielectric materials. The protective layer 121 may be formed by material deposition methods such as optical vapor deposition, physical vapor deposition, and/or atomic layer deposition.

The through-holes may be used to expose the overflow doping regions 110 to achieve external interconnection.

Specifically, the through-holes may be formed by exposing and etching the protective layer 121 using photolithography techniques. The bottoms of the through-holes expose the overflow doping regions 110.

In order to prevent contact resistance and ensure electrical connectivity stability, at least two through-holes may be formed at the locations corresponding to the overflow doping regions 110.

After the formation of the through-holes, conductive material is deposited within the through-holes to form overflow interconnection structures 120.

As shown in FIG. 5, the overflow interconnection structures 120 include plugs 122 and conductive layers 123. For example, the plugs 122 are within the through-holes, and the conductive layers 123 are connected to the plugs 122, covering the surface of the protective layer 121.

In some embodiments of the present disclosure, on the second surface 102, the projections of the memory nodes may be within the projection range of the overflow interconnection structures 120. In other words, on the second surface 102, the projections of the memory nodes may be within the projection range of the conductive layers 123 corresponding to the overflow interconnection structures 120, thereby allowing the conductive layers 123 to cover the memory nodes. This configuration may achieve optical isolation of the memory nodes and prevent incident light from reaching the memory nodes effectively. Thus, the thickness of the conductive layers 123 may be in the range of 50 nm to 200 nm.

Specifically, the steps for forming the overflow interconnection structures 120 within the through-holes may include: depositing conductive material within the through-holes, with the conductive material extending onto the surface of the protective layer 121; removing a portion of the conductive material to expose the protective layer 121 over the second surface 102 corresponding to the photosensitive element (pd). The conductive material may be tungsten. In other words, the material of the overflow interconnection structures 120 may be tungsten.

It should be noted that, in some embodiments illustrated in FIG. 5, the formation method may further include: forming interconnectors (not labeled) connecting the plurality overflow interconnection structures 120.

By connecting the overflow interconnection structures 120 through the interconnectors, parallel connections of the plurality of vertical-overflow-drain structures may be achieved. It may also enable the simultaneous activation of the vertical-overflow-drain structures, improve the synchronization of the vertical-overflow-drain structures effectively and reduce control complexity.

Correspondingly, the present disclosure may also provide a pixel unit for an optical detector.

FIG. 5 illustrates a schematic cross-sectional view of an exemplary pixel unit in an optical detector according to the present disclosure.

The pixel unit may include: a base 103, the base 103 including a substrate 100 having a first surface 101 and a second surface 102 opposite to the first surface 101; a photosensitive element (pd) in the first surface 101 of the substrate 100; a plurality of memory nodes in the first surface 101 of the substrate 100 and spaced apart from the photosensitive element (pd); a plurality of overflow doping regions 110 in the second surface 102 of the substrate 100, where the second surface 102 is opposite to the first surface 101, locations of the overflow doping regions 110 correspond to locations of the memory nodes, and a doping type of the overflow doping regions 110 is same as a doping type of the doping regions of the memory nodes; a plurality of overflow interconnection structures 120 over the overflow doping regions 110 and electrically connected to the overflow doping regions 110.

It should be noted that the optical detector including the pixel unit may be formed by the formation method of the optical detector disclosed in the present disclosure. Therefore, the specific technical solution of the pixel unit can refer to the embodiments of the formation method of the optical detector mentioned above.

The base 103 may be used to provide a foundation of processes for subsequent steps.

The substrate 100 may be used to provide a working platform for subsequent processes. The material of the substrate 100 may include single-crystal silicon, polycrystalline silicon, and/or amorphous silicon. The material of the substrate 100 may include silicon, germanium, gallium arsenide, and/or silicon-germanium compounds. The substrate 100 may also include those with epitaxial layers and/or silicon structures on epitaxial layers. The material of the substrate 100 may include other semiconductor materials, and the present disclosure is not limited thereto. As shown in FIG. 3, the material of the substrate 100 is silicon.

The photosensitive device (pd) in the first surface 101 is used to absorb photons and perform photoelectric conversion to generate photogenerated carriers.

In some embodiments of the present disclosure, the photosensitive element (pd) may include: a PN junction PN in the first surface 101. Specifically, as shown in FIG. 3, the photosensitive device (pd) includes: a P-type photosensitive doping region PNp and an N-type photosensitive doping region PNn. For example, the P-type photosensitive doping region PNp and the N-type photosensitive doping region PNn are along the direction from the first surface 101 to the second surface 102 sequentially, and both are in contact with each other to form the PN junction PN.

The memory nodes may be used to store photogenerated carriers.

In some embodiments of the present disclosure, the optical detector may be an indirect time-of-flight three-dimensional optical detector. The photogenerated carriers stored by the memory node may be used to calculate the phase difference. Therefore, the plurality of memory nodes may be in the base 103. In other words, the plurality of memory nodes may be in the substrate 100.

Specifically, in the embodiments shown in FIG. 3, the pixel unit includes the memory node mn1 and the memory node mn2. For example, in the plane parallel to the first surface 101, the memory node mn1 and the memory node mn2 are on either side of the photosensitive element (pd) in the substrate 100.

As shown in FIG. 3, the memory nodes include storage doping regions. Thus, the pixel unit include a storage doping region N1 and a storage doping region N2. The storage doping region N1 and the storage doping region N2 are in the plane parallel to the first surface 101 and on either side of the PN junction PN in the first surface 101 respectively.

In some embodiments of the present disclosure, the substrate 100 is a P-doped substrate. Therefore, the storage doping regions are N-doped regions, i.e., both the storage doping region N1 and the storage doping region N2 are N-doped regions.

Specifically, in some embodiments illustrated in FIG. 3, the doping concentration of the substrate 100 may be less than 10¹³/cm³; the doping concentrations of the storage doping regions of the memory nodes may be greater than 10¹⁷/cm³; and the doping concentrations of the P-type photosensitive doping region PNp and the N-type photosensitive doping region PNn may be greater than 10¹⁵/cm³.

Furthermore, the base 103 may also include: switch devices between the photosensitive device (pd) and the memory nodes to control the conduction and cutoff.

Specifically, the base 103 may include: a PN junction PN in the first surface 101 of the substrate 100; a storage doping regions N1 and a storage doping regions N2 on either side of the PN junction PN in the first surface 101; a switch device tx1 over the first surface 101 between the storage doping region N1 and the PN junction PN; a switch device tx2 over the first surface 101 between the storage doping region N2 and the PN junction PN.

A plurality of vertical-overflow-drain structures may be formed between overflow doping regions 110 and the memory nodes, allowing charges stored in the memory nodes to be discharged at a certain rate. This configuration may reduce the oversaturation of memory nodes and solve background noise issue effectively.

Furthermore, the overflow doping regions 110 are formed in the second surface 102 of the substrate 100, where the second face 102 is opposite to the first surface 101. Therefore, the formation of the overflow doping regions 110 may not affect the area of the pixel unit and the resolution of optical detector may not be compromised.

In some embodiments of the present disclosure, the substrate 100 is a P-doped substrate, and the storage doping regions of the memory nodes are N-doped regions. Therefore, the overflow doping regions 110 are N-doped regions. This configuration may allow for the formation of NPN vertical-overflow-drain structures between the memory nodes, the substrate 100, and the overflow doping regions 110.

In some embodiments of the present disclosure, the peak doping depth of the overflow doping regions 110 may be less than 0.1 μm. By controlling the doping peak depth of the overflow doping regions 110 to form shallow lightly doped regions, it may minimize the adverse effects on the performance of the photosensitive element (pd) and memory nodes and also aid in controlling the thickness of the substrate 110 while facilitating the formation of the vertical-overflow-drain structures, even when the overflow doping regions 110 are formed closely to the surface of the second surface 102. For example, the doping concentration of the overflow doping regions 110 may be greater than 10¹⁷/cm³.

As shown in FIG. 3 and FIG. 4, in some embodiments of the present disclosure, the plurality of memory nodes are in the base 103. Therefore, the plurality of overflow doping regions 110 are in the second surface 102 of substrate 100, and one of the plurality of overflow doping regions 110 corresponds to one of the plurality of memory nodes.

One of the plurality of overflow doping regions 110 may correspond to one of the plurality of memory nodes. In other words, a vertical-overflow-drain structure may be formed between one of the plurality of overflow doping regions 110, its corresponding memory node, and the substrate therebetween, thereby forming an electron outflow channel to reduce the oversaturation of the corresponding memory node.

Specifically, one of the plurality of overflow doping regions 110 may correspond to one of the plurality of memory nodes. Therefore, on the second surface 102, the projections of the storage doping region of the memory nodes may be within the range of the corresponding overflow doping regions 110. As shown in FIG. 4, on the second surface 102, the projection of storage doping region N1 is within the range of the corresponding overflow doping region 110, and the projection of storage doping region N2 is within the range of the corresponding overflow doping region 110.

In the direction parallel to the second surface 102, the regions with dopant ions may cover the entire pixel unit. In the second surface 102, the regions with dopant ions that corresponds to the memory nodes may be the overflow doping regions 110. The regions with dopant ions may also extend to the area corresponding to the photosensitive element (pd).

As shown in FIG. 5, in the second surface 102, the regions with dopant ions extends from the region corresponding to the memory node mn1, through the region corresponding to the photosensitive element (pd), and into the region corresponding to the memory node mn2.

In some embodiments of the present disclosure, the pixel unit may also include deep trench isolation structures 130, which may be used to form one of the plurality of overflow doping regions 110 corresponding to one of the plurality of memory nodes.

As shown in FIG. 5, in some embodiments of the present disclosure, the deep trench isolation structures 130 extend to the depth of the PN junction PN, and the distance d between the end of the deep trench isolation structure 130 and the first surface 101 may be greater than 0.3 μm. The deep trench isolation structures 130 are between the photosensitive element (pd) and the memory nodes, and extend deep into the substrate 100, reaching the depth of the PN junction PN. This configuration may ensure electrical isolation and optical isolation between the photosensitive element (pd) and the memory nodes. Additionally, it may limit the distance d between the end of the deep trench isolation structure 130 and the first surface 101 to ensure normal electron flow between the photosensitive element (pd) and the memory nodes when a switch device is activated.

In some embodiments of the present disclosure, the deep trench isolation structures 130 may include: a first material layer and a second material layer, where the first material layer is between the second material layer and the substrate 100. When both the first material layer and the second material layer are dielectric layers, the refractive index of the second material layer may be greater than the refractive index of the first material layer. Or the first material layer may be a dielectric layer, and the second material layer may be a metal layer.

In some embodiments illustrated in FIG. 5, the material of the first material layer is silicon dioxide, and the material of the second material layer is silicon nitride. In some other embodiments of the present disclosure, the material of the second material layer may include copper, tungsten, and/or aluminum. Specifically, the thickness of the first material layer may be in the range of 50 nm to 200 nm, and the thickness of the second material layer is may be in the range of 100 nm to 400 nm.

The overflow interconnection structures 120 may be suitable for forming connections between the overflow doping regions 110 and external circuits, thereby facilitating the flow of charge by connecting the vertical-overflow-drain structures to external circuits.

In some embodiments of the present disclosure, the plurality of memory nodes are formed in the base 103. The plurality of overflow doping regions 110 are formed in the second surface 102 of the substrate 100, where one of the plurality of overflow doping regions 110 corresponds to one of the plurality of memory nodes. Therefore, the plurality of overflow interconnection structures 120 are over the overflow doping regions 110, and one of the plurality of overflow interconnection structures 120 corresponds to one of the plurality of overflow doping regions 110.

In some embodiments of the present disclosure, on the second surface 102, the projections of the memory nodes may be within the projections of the overflow interconnection structures 120. The optical detector is a back-illuminated optical detector, where light enters from the second surface 102 to the substrate 100. By ensuring that the projections of the memory nodes fall within the projections of the overflow interconnection structures 120, even if the overflow interconnect structure 120 covers the memory nodes, optical isolation of the memory nodes may be achieved. It may also prevent incident light from reaching the memory nodes and the formation of parasitic photoelectrons effectively.

As shown in FIG. 5, the pixel unit further includes: a protective layer 121 over the second surface 102. For example, the protective layer 121 is used to achieve electrical insulation between the overflow doping regions 110 and the overflow interconnection structures 120. Specifically, the material of the protective layer 121 may include silicon dioxide. In other embodiments of the present disclosure, the material of the protective layer 121 may also be other dielectric materials.

As shown in FIG. 5, the overflow interconnection structures 120 includes plugs 122 and conductive layers 123. The plugs 122 pass through the protective layer 121, and the conductive layers 123 are connected to the plugs 122, covering the surface of the protective layer 121.

In some embodiments of the present disclosure, on the second surface 102, the projections of the memory nodes may be within the projections of the overflow interconnection structures 120. In other words, on the second surface 102, the projections of the memory nodes may be within the projections of the conductive layers 123 of the corresponding overflow interconnection structures 120. The configuration may ensure that the conductive layers 123 cover the memory nodes, enabling optical isolation of the memory nodes and preventing incident light from reaching the memory nodes effectively.

Specifically, the material of the overflow interconnection structures 120 may be tungsten. In other words, the material of the plugs 122 and the conductive layers 123 may be tungsten.

It should be noted that, in some embodiments illustrated in FIG. 5, the pixel unit may further include a plurality of interconnectors, where the interconnectors connect the plurality of overflow interconnection structures 120.

By connecting the overflow interconnection structures 120 through the interconnectors, parallel connections of the plurality of vertical-overflow-drain structures may be achieved. It may also enable the simultaneous activation of the vertical-overflow-drain structures, improve the synchronization of the vertical-overflow-drain structures effectively and reduce control complexity.

Correspondingly, the present disclosure may also provide an optical detector, where the optical detector includes a pixel unit, and the pixel unit is the pixel unit disclosed in the present disclosure. Specific technical solutions of the optical detector can be referred to in the embodiments of the pixel unit described above; however, further elaboration on this is omitted herein.

Moreover, the optical detector can be formed using the formation method of the optical detector disclosed in the present disclosure, and specific technical solutions of the optical detector can be referred to in the embodiments of the formation method of the optical detector described above; however, further elaboration on this is omitted herein.

Correspondingly, the present disclosure may provide a readout method for an optical detector.

The optical detector is the optical detector disclosed in the present disclosure.

FIG. 5 illustrates a schematic cross-sectional view of an exemplary pixel unit in an optical detector according to the present disclosure. Since the optical detector is the optical detector disclosed in the present disclosure, specific technical solutions for the optical detector can be found in the embodiments of the optical detector described above; however, further elaboration on this is omitted herein.

One of the plurality of memory nodes may be connected to the photosensitive element (pd) via a switch device. Specifically, as shown in FIG. 5, the memory node mn1 is connected to the photosensitive element (pd) via the switch device tx1, and the memory node mn2 is connected to the photosensitive element (pd) via the switch device tx2.

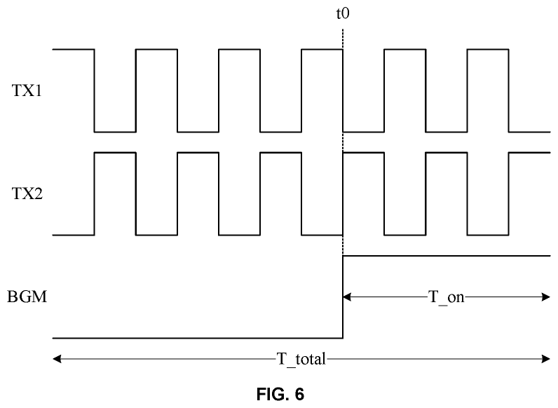

FIG. 6 illustrates a schematic of timing diagram of signal in an exposure process of an exemplary pixel unit in an exemplary readout method of an optical detector according to some embodiments of the present disclosure.

It should be noted that the substrate 100 may be a P-doped substrate, and the memory nodes may include storage doping regions, where the storage doping regions are N-doped regions; the overflow doping regions 110 are N-doped regions.

When a connection terminal BMG transitions from a low potential to a high potential, the NPN-type transistor formed by the storage doping regions, the overflow doping regions 110, and the substrate 100 may become conductive, allowing the charge stored in the memory nodes to be discharged from the connection terminal BMG at a certain rate.

The optical detector is an indirect time-of-flight three-dimensional optical detector, and it calculates the distance based on the difference in the stored charge between the memory node mn1 and the memory node mn2. Therefore, the memory node mn1 and the memory node mn2 may release an equal amount of charge, which may not affect the distance calculation result of the optical detector.

The readout method may include: activating and deactivating the plurality of switch devices alternately at a predetermined frequency during one exposure cycle; connecting the plurality of overflow interconnection structures 120 to external circuits simultaneously at predetermined time points to discharge charge at the same rate.

As shown in FIG. 6, the switch device tx1 and the switch device tx2 load high potential alternately within a complete exposure cycle T_total, i.e., the switch device tx1 and the switch device tx2 activate alternately. Starting at the predetermined time point to, a high potential is applied to the plurality of overflow interconnection structures 120 simultaneously, where the plurality of overflow interconnection structures 120 are connected to the connection terminal BMG. Thus, starting at the predetermined time point t0, a high potential is applied to the connection terminal BMG, and the memory node mn1 and the memory node mn2 discharge charge at the same rate.

For example, after the time point t0 is set, a high potential continues being applied to the plurality of overflow interconnection structures. Thus, the memory node mn1 and the memory node mn2 discharge charge at the same rate within the activation time T_on.

It should be noted that in some embodiments of the present disclosure, in the step of connecting the first overflow interconnection structure and the second overflow interconnection structure to the external circuit simultaneously at the predetermined time point to, a predetermined time point may be set based on ambient light. In other words, the time duration of triode conduction may be determined based on ambient light in order to achieve the suppression of ambient light and the prevention of oversaturation.

As disclosed, the overflow doping region may be in the second surface of the substrate, where the second surface is opposite to the first surface. The locations of the overflow doping regions correspond to the locations of the memory nodes, and the doping type of the overflow doping regions may be the same as that of the doping regions of the memory nodes. The vertical-overflow-drain structures (VOD) may be formed between the overflow doping regions and the memory nodes, allowing charge stored in the memory nodes to be discharged at a certain rate through the overflow interconnection structures. This configuration may reduce the oversaturation of memory nodes effectively without changing the exposure time or affecting circuit power consumption, thus improving background noise issue. Furthermore, the memory nodes and the overflow doping regions are in the first and second surfaces of the substrate, respectively, thus the placement of the overflow doping regions may not affect the area of pixel unit area and the resolution of the optical detector may not be compromised.

Additionally, the pre-doping region may be formed in the second surface by maskless ion implantation, and the pre-doping region extends from the locations corresponding to the memory nodes to the location corresponding to the photosensitive element. The pre-doping region may be separated to form overflow doping regions by deep trench isolation structures passing through the thickness of the substrate. The method of forming the pre-doping region by maskless ion implantation may reduce process costs effectively and controls process complexity.

Furthermore, the overflow interconnection structures may pass through the protective layer, reach the overflow doping regions and further extend onto the protective layer over the overflow doping regions. On the second surface, the projections of the memory nodes may be within the projection range of the overflow interconnection structures. The overflow interconnection structures may not only connect the overflow doping regions to external circuits but also serve as optical isolation. It may also prevent incident light from reaching the memory nodes and the formation of parasitic photoelectrons effectively.

Compared to existing technologies, the technical solution of the present disclosure offers the following advantages.

In the technical solution of the present disclosure, the overflow doping regions are in the second surface of the substrate, where the second surface is opposite to the first surface. The locations of the overflow doping regions correspond to the locations of the memory nodes, and the doping type of the overflow doping regions is the same as the doping type of the doping regions of the memory nodes. Vertical-overflow-drain (VOD) structures are formed between the overflow doping regions and the memory nodes, allowing the charge stored in the memory nodes to be discharged at a certain rate through the overflow interconnection structures, without altering the exposure time or affecting circuit power consumption. This may reduce the oversaturation of memory nodes effectively and solve background noise issue. Furthermore, the memory nodes and the overflow doping regions are in the first and second surfaces of the substrate, respectively, ensuring that the placement of the overflow doping region does not affect the area of the pixel unit, thereby preserving the resolution of the optical detector.

In an optional embodiment of the present disclosure, a pre-doping region is formed in the second surface using maskless ion implantation. The pre-doping region extends from the locations corresponding to the memory nodes to the location corresponding to the photosensitive element. The pre-doping region is separated to form the overflow doping regions by deep trench isolation structures that pass through the thickness of the substrate. The maskless ion implantation process may reduce process costs and control process complexity effectively.

In another optional embodiment of the present disclosure, the overflow interconnection structures pass through the protective layer and are in contact with the overflow doping regions. Additionally, the overflow interconnection structures extend onto the protective layer over the overflow doping region. On the second surface, the projections of the memory nodes are within the projection range of the overflow interconnection structures. The overflow interconnection structures not only facilitate the connection between the overflow doping regions and external circuits but also serve as optical isolation, preventing incident light from reaching the memory nodes and the formation of parasitic photoelectrons effectively.

Although the present disclosure has been described above, it is not limited thereto. Those skilled in the art may make various changes and modifications within the spirit and scope of the present disclosure. Therefore, the scope of protection of the present disclosure should be determined according to the scope defined by the claims.

What is claimed is:

1. A pixel unit for an optical detector, comprising:
a base, including a substrate having a first surface and a second surface opposite to the first surface;
a photosensitive element in the first surface of the substrate;
a plurality of memory nodes in the first surface of the substrate, wherein the plurality of memory nodes are spaced apart from the photosensitive element;
a plurality of overflow doping regions in the second surface of the substrate, wherein locations of the plurality of overflow doping regions correspond to locations of the plurality of memory nodes, and a doping type of the plurality of overflow doping regions is same as a doping type of the plurality of doping regions of the plurality of memory nodes; and
a plurality of overflow interconnection structures over the plurality of overflow doping regions, wherein the plurality of overflow interconnection structures are electrically connected to the plurality of overflow doping regions.

2. The pixel unit according to claim 1, further comprising:
a plurality of deep trench isolation structures in the base between the photosensitive element and the plurality of memory nodes, the plurality of deep trench isolation structures extending from the second surface to the first surface and passing through the at least thickness of the plurality of overflow doping regions.

3. The pixel unit according to claim 2, wherein the pixel unit comprises a pre-doping region in the second surface of the substrate, and the pre-doping region extends from locations corresponding to the plurality of memory nodes to location corresponding to the photosensitive element; and
the pre-doping region at the locations corresponding to the plurality of memory nodes is suitable for forming the plurality of overflow doping regions.

4. The pixel unit according to claim 1, wherein a doping peak depth of the plurality of overflow doping regions is less than 0.1 μm.

5. The pixel unit according to claim 2, wherein the photosensitive element comprises: a PN junction in the first surface of the substrate; and
the plurality of deep trench isolation structures extend to the location where the PN junction forms, and the distance between the end of the plurality of deep trench isolation structures and the first surface is greater than 0.3 μm.

6. The pixel unit according to claim 1, wherein a doping concentration of the plurality of overflow doping regions is greater than 10¹⁷/cm³.

7. The pixel unit according to claim 1, further comprising:
a protective layer over the second surface, wherein the protective layer is at least over the plurality of overflow doping regions;
a plurality of overflow interconnection structures passing through the protective layer and in contact with the plurality of overflow doping regions, the overflow interconnection structures further extending onto the protective layer over the plurality of overflow doping regions.

8. The pixel unit according to claim 7, wherein the projection of the plurality of memory nodes are within the projection range of the plurality of overflow interconnection structures on the second surface.

9. The pixel unit according to claim 1, wherein the optical detector is an indirect time-of-flight three-dimensional optical detector.

10. The pixel unit according to claim 9, wherein the plurality of memory nodes are in the base; and
the plurality of overflow doping regions are in the second surface of the substrate, and one of the plurality of overflow doping regions corresponds to one of the plurality of memory nodes; and
the plurality of overflow interconnection structures are in the pixel unit, and one of the plurality of overflow interconnection structures corresponds to one of the plurality of overflow doping regions.

11. The pixel unit according to claim 1, further comprising: a plurality of interconnectors, wherein the plurality of interconnectors connect the plurality of overflow interconnection structures.

12. The pixel unit according to claim 1, wherein the substrate is a P-doped substrate, and the plurality of memory nodes comprise: a plurality of storage doping regions, wherein the plurality of storage doping regions are N-doped regions; and
the plurality of overflow doping regions are N-doped regions.

13. An optical detector, comprising:
a pixel unit comprising the pixel unit according to claim 1.

14. A method for forming an optical detector, comprising:
providing a base including a substrate having a first surface and a second surface opposite to the first surface;
providing a photosensitive element in the first surface of the substrate;
providing a plurality of memory nodes in the first surface of the substrate, wherein the plurality of memory nodes are spaced apart from the photosensitive element;
forming a plurality of overflow doping regions in the second surface of the substrate, wherein the second surface is opposite to the first surface, locations of the plurality of overflow doping regions correspond to locations of the plurality of memory nodes, and a doping type of the plurality of overflow doping regions is same as a doping type of the plurality of doping regions of the memory nodes; and
forming a plurality of overflow interconnection structures over the plurality of overflow doping regions, wherein the plurality of overflow interconnection structures are electrically connected to the plurality of overflow doping regions.

15. The method according to claim 14, wherein forming the plurality of overflow doping regions in the second surface of the substrate comprises:
forming a pre-doping region in the second surface, wherein the pre-doping region is at least at a location corresponding to locations of the plurality of memory nodes; and
forming a plurality of deep trench isolation structures in the base between the photosensitive element and the plurality of memory nodes, wherein the plurality of deep trench isolation structures extend from the second surface toward the first surface and at least pass through the pre-doping region.

16. The method according to claim 15, wherein the pre-doping region is formed in the second surface by maskless ion implantation when forming the pre-doping region in the second surface.

17. The method according to claim 14, wherein forming the plurality of overflow interconnection structures over the plurality of overflow doping regions comprises:
forming a protective layer over the second surface, wherein the protective layer is at least over the plurality of overflow doping regions;
forming a plurality of through-holes passing through the protective layer, wherein the plurality of through-holes are over the plurality of overflow doping regions and expose the bottom of the plurality of overflow doping regions; and
forming a plurality of overflow interconnection structures in the plurality of through-holes, the plurality of overflow interconnection structures extending onto the protective layer over the plurality of overflow doping regions.

18. The method according to claim 14, further comprising: forming a plurality of interconnectors connecting to the plurality of overflow interconnection structures.

19. A readout method for an optical detector comprising the pixel unit according to claim 1, the method comprising:
activating and deactivating a plurality of switch devices alternately at a predetermined frequency during one exposure cycle, wherein each of the plurality of memory nodes connects to the photosensitive element via one of the plurality of switch devices; and
connecting the plurality of overflow interconnection structures to external circuits simultaneously at predetermined time points to discharge charge at the same rate.

20. The readout method according to claim 19, wherein the substrate is a P-doped substrate, and the plurality of memory nodes comprise: a plurality of storage doping regions, wherein the plurality of storage doping regions are N-doped regions; and
the plurality of the overflow doping regions are N-doped regions; and
a high potential is loaded to the plurality of overflow interconnection structures simultaneously at predetermined time points in the step of connecting the plurality of overflow interconnection structures to external circuits simultaneously at predetermined time points.
